(19) United States
(12) Patent Application Publication
(10) Pub. No.: US 2009/0211800 A1
(43) Pub. Date: Aug. 27, 2009

(54) ELECTROMAGNETIC SHIELDING DEVICE

(75) Inventors: Wei-Chun Tsao, Taipei City (TW); Chien-Ru Lin, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNIHAN CORPORATION, Taipei City (TW)

(21) Appl. No.: 12/356,080

(22) Filed: Jan. 20, 2009

(30) Foreign Application Priority Data
Feb. 26, 2008 (TW) 97106640

(51) Int. Cl. H05K 9/00

(52) U.S. Cl. 174/377; 361/818

(57) ABSTRACT

An electromagnetic shielding device includes a frame and a cover. The frame is formed by bending a strip structure and disposed on a circuit board with an electronic component, and it encloses the electronic component. The cover has a top portion and a plurality of side portions. The side portions are expended and bent from the top portion. When the cover is combined with the frame to enclose the electronic component, the side portions are closely connected to the frame. The cover and the frame are combined to form a shielding space.

### CROSS-REFERENCE TO RELATED APPLICATION

This application claims the priority benefit of Taiwan application serial no. 97106640, filed on Feb. 26, 2008. The entirety of the above-mentioned patent application is hereby incorporated by reference herein and made a part of specification.

### BACKGROUND OF THE INVENTION

1. Field of the Invention

The invention relates to a shielding device and, more particularly, to an electromagnetic shielding device for an electronic component.

2. Description of the Related Art

Electromagnetic interference (EMI) is a common problem in an interior of an electronic product. In detail, an electronic component of the electronic product may usually generate electromagnetic waves during operating, and the electromagnetic waves may affect signal quality and operating performance of the other electronic components. Therefore, electromagnetic interference protection is an important detecting index of the electronic product.

Taking a tuner as an example, when the tuner adjusts the operating frequency of the electronic product, the tuner is easy to generate electromagnetic waves and affect performance of the other electronic components. In the same way, with increase of the signal processing speed and concentration of the wiring, the electromagnetic waves generated by the electronic component are easy to interfere with frequency adjusting performance of the tuner.

### BRIEF SUMMARY OF THE INVENTION

The invention provides an electromagnetic shielding device for preventing electromagnetic waves from leaking and preventing external electromagnetic waves from permeating.

The invention provides an electromagnetic shielding device, and the device includes a frame and a cover. The frame is formed by bending a strip structure and disposed on a circuit board with an electronic component, and it encloses the electronic component. The cover has a top portion and a plurality of side portions. The side portions are expended and bent from the top portion. When the cover is combined with the frame to enclose the electronic component, the side portions are connected closely to the frame, and the cover and the frame are combined to form a shielding space.

In an embodiment of the invention, a joint gap is formed between the two adjacent side portions, and the top portion has a plurality of first depressed portions. Each of the first depressed portions is near to the joint gap between the two adjacent side portions. When the cover is combined with the frame, the first depressed portions may prevent the joint gaps from exposing the shielding space.

In an embodiment of the invention, the top portion further has a plurality of second depressed portions, and the second depressed portions are arranged at the top portion near to the side portions.

In an embodiment of the invention, one end of the strip structure bent into the frame is folded to overlap the other end.

In an embodiment of the invention, the frame has a second fastening indentation, and each of the side portions has a first fastening indentation. When the cover is combined with the frame, the second fastening indentation is fastened with the corresponding first fastening indentation.

In an embodiment of the invention, the frame has a plurality of pins, and the circuit board has a plurality of disposed holes. The pins pass through the disposed holes.

In an embodiment of the invention, a connector is disposed through the frame, and it is electrically connected with the electronic component.

In an embodiment of the invention, the electronic component is a tuner.

In the invention, a strip plate is formed by stamping using a die. The strip plate is bent into a frame with a predetermined shape via a suitable machine such as a folding bed. In addition, after the cover is bent and folded to form the side portions, a joint gap may be formed between two adjacent side portions. In the invention, when the cover is combined with the frame, most of the joint gaps of the side portions may be shielded by the frame without joint gaps. In addition, as the depressed portions may be disposed at the places of the top portion near to the joint gaps, the rest joint gaps of the side portions may also be shielded by the depressed cover to prevent the joint gaps from exposing the shielding space. Thus, the electromagnetic shielding device may have a better electromagnetic shielding ability to prevent the electromagnetic waves generated by the electronic components from leaking and prevent the external electromagnetic waves from permeating into the electromagnetic shielding device.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing an electromagnetic shielding device disposed on a circuit board for shielding an electronic component on the circuit board according to an embodiment of the invention.

FIG. 1B is an exploded diagram of the electromagnetic shielding device and the circuit board in FIG. 1A.

FIG. 2A is an assembly diagram of an electromagnetic shielding device according to another embodiment of the invention.

FIG. 2B is an exploded diagram of the electromagnetic shielding device in FIG. 2A.

### DETAILED DESCRIPTION OF THE EMBODIMENTS

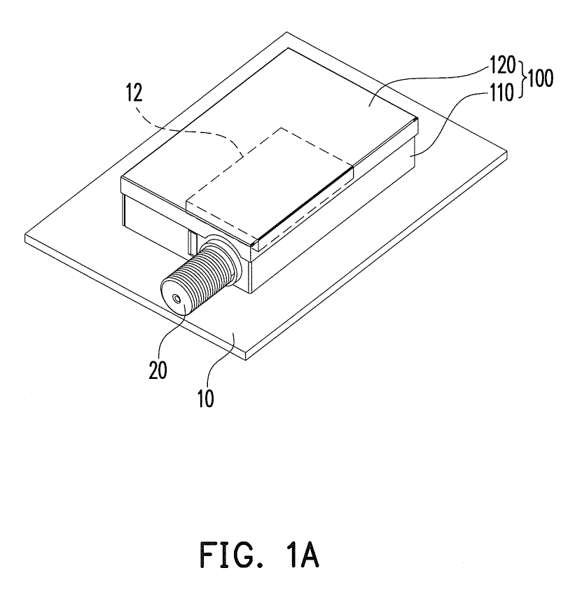

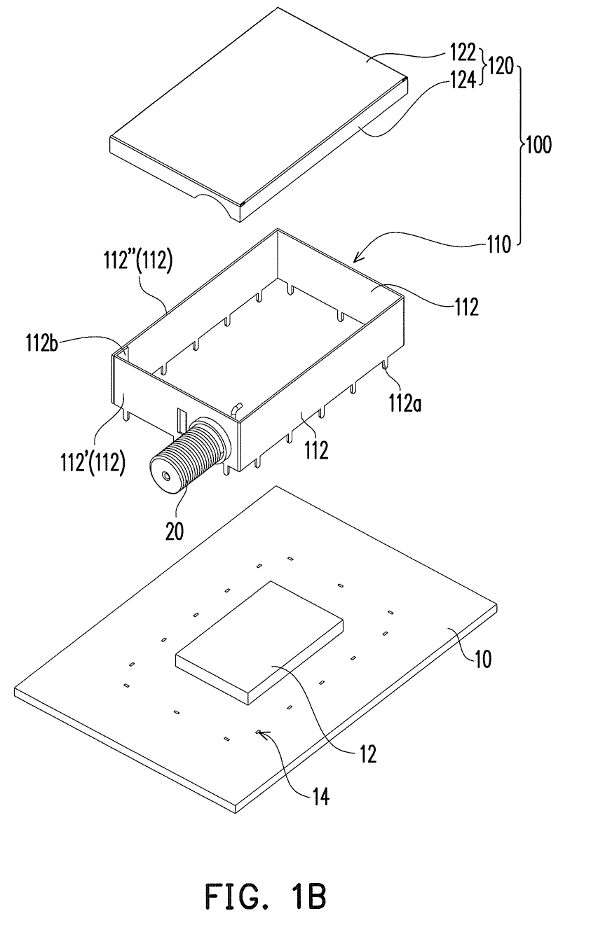

FIG. 1A is a schematic diagram showing an electromagnetic shielding device disposed on a circuit board for shielding an electronic component on the circuit board according to an embodiment of the invention. FIG. 1B is an exploded diagram of the electromagnetic shielding device and the circuit board in FIG. 1A.

As shown in FIG. 1A and FIG. 1B, in the embodiment, an electromagnetic shielding device 100 is suitable to be disposed on a circuit board 10 having an electronic component 12. The electronic component 12 shown in FIG. 1B is, for example, a tuner. The electromagnetic shielding device 100 is used to protect the tuner to prevent external electromagnetic waves from permeating into the electromagnetic shielding device 100. Thus, the tuner can operate normally. The electromagnetic shielding device 100 may also prevent the electromagnetic waves generated by the tuner from leaking to affect operating performance of the other electronic components.

In the embodiment, the electromagnetic shielding device 100 mainly includes a frame 110 and a cover 120. In the embodiment, the frame 110 is, for example, fastened to the circuit board 10 via a surface mount technology (SMT) or in other suitable modes, and the frame 110 encloses the electronic component 12. In detail, the frame 110 of the embodiment is a quadrate frame. The frame 110 may be manufactured as follows. First, a strip plate is formed by stamping using a die, and then the strip plate is bent into a frame structure such as a quadrilateral frame via a suitable machine such as a folding bed. The frame 110 of the embodiment may include a plurality of frame side portions 112, and no joint gap is formed between the two adjacent frame side portions 112.

A connector 20 is disposed through the frame side portions 112. The connector 20 is used to connect external transmission circuits, and it transmits signals to the electronic component 12. The frame side portions 112 have a plurality of pins 112a, and the circuit board 10 has a plurality of disposed holes 14 that correspond to the pins 112a. The pins 112a pass through the disposed holes 14 via a suitable process to make the frame 110 stably assembled on the circuit board.

To prevent the electromagnetic waves from passing through the joint gaps of the external surface of the frame 110, in the embodiment, a lateral side of a frame side portion 112′ is bent into a folded sheet 112b, and the folded sheet 112b overlaps a surface of another frame side portion 112″ to totally seal the joint gaps of the external surface of the frame 110. Thus, a closed frame body 110 of the embodiment is formed.

In the embodiment, the frame 110 is, for example, a quadrilateral frame structure. In other embodiments, the frame 110 may also be other polygonal frame structures, which is not limited herein.

In addition, in the embodiment, the cover 120 is suitable to be combined with the frame 110 to enclose the electronic component 12, and the cover 120 and the frame 110 are combined to form a shielding space. Thus, the objective of preventing the electromagnetic waves generated by the electronic component 12 from leaking or the objective of preventing the external electromagnetic waves from permeating into the electromagnetic shielding device 100 may be achieved.

In detail, the cover 120 includes a top portion 122 and a plurality of side portions 124. The side portions 124 are bent from the top portion 122, and they may cover the frame 112. When the cover 120 is combined with the frame 110, since the frame body 112 does not have joint gaps and the top portion 122 may cover the electronic component 12, the side portions 124 are closely connected to the frame 112. Thus, the external electromagnetic waves are not easy to permeate into the electromagnetic shielding device 100, and the operating performance of the electronic component 12 is not easy to affect. In the same way, since the electronic component 12 is shielded by the electromagnetic shielding device 100, the electromagnetic waves generated by the electronic component 12 may not easily leak and interfere with the other electronic components on the circuit board 10.

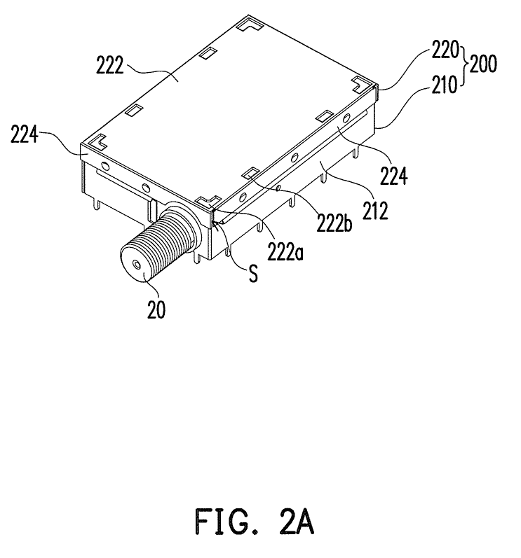

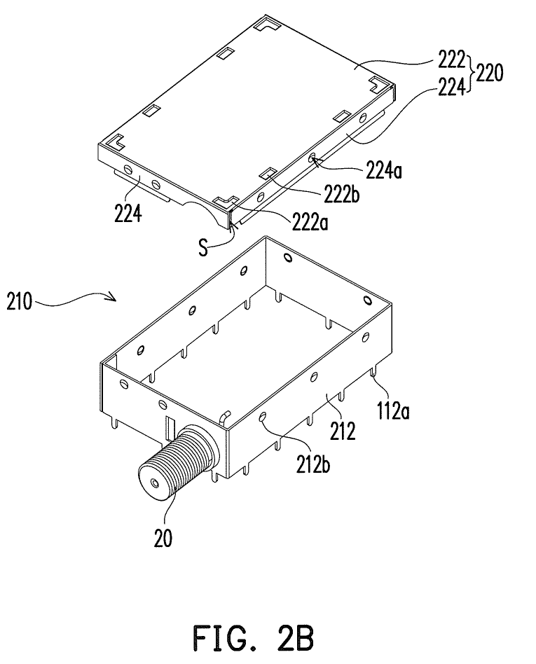

In another aspect, to provide a better electromagnetic shielding effect for the electromagnetic shielding device, the invention provides another embodiment to improve the electromagnetic shielding ability of the electromagnetic shielding device hereinbelow. FIG. 2A is an assembly diagram of an electromagnetic shielding device according to another embodiment of the invention. FIG. 2B is an exploded diagram of the electromagnetic shielding device in FIG. 2A.

As shown in FIG. 2A and FIG. 2B, the electromagnetic shielding device 200 of the embodiment is similar with the electromagnetic shielding device 100 of the above embodiment. The difference between them is that a top portion 222 of a cover 220 in the embodiment further has a plurality of first depressed portions 222a to improve the overall electromagnetic shielding ability of the electromagnetic shielding device 200. The description of how to use the design of the first depressed portions 222a to improve the overall electromagnetic shielding ability of the electromagnetic shielding device 200 is described hereinbelow in detail.

After the cover body 220 is bent and folded by a suitable machine to form the side portions 224, a joint gap S may be formed between the two adjacent side portions 224. Therefore, in the embodiment, the top portion 222 of the cover 220 may have a plurality of first depressed portions 222a, and each of the first depressed portions 222a is disposed at the place of the top portion 222 near to the joint gap S between the two adjacent side portions 224. Thus, when the cover 220 is combined with the frame 210, the first depressed portions 222a can prevent the joint gaps S from exposing the shielding space.

In detail, since no joint gap is formed between the frame side portions 212, when the cover 220 totally is combined with frame 210, the joint portion of the two adjacent frame side portions 212 may shield most of the joint gap S, and the first depressed portion 222a disposed near to the joint gap S may shield the rest joint gap via the depressed cover to prevent the external electromagnetic waves from passing through the joint gap S to interfere with the electronic component protected by the electromagnetic shielding device 200. The electromagnetic waves generated by the electronic components are shielded by the electromagnetic shielding device 200 and may not interfere with the other electronic components. In other words, the joint gaps S on the cover 220 may not expose the shielding space. Thus, the electromagnetic shielding device 200 has a better electromagnetic shielding ability.

In addition, in the embodiment, the top portion 222 of the cover 220 may have a plurality of second depressed portions 222b. The second depressed portions 222b are, for example, arranged at the top portion 222 near to the side portions 224 to increase structure strength of the cover 220. Furthermore, to provide a better fixed combination characteristic for the cover 220 and the frame 210, in the embodiment, the frame 212 may have at least one second fastening indentation 212b. Each of the side portions 224 has at least one first fastening indentation 224a corresponding to the second fastening indentation 212b. When the cover 220 is combined with the frame 210, the second fastening indentations 212b may be fastened with the corresponding first fastening indentations 224a. Thus, the cover 220 is fastened to the frame 210 stably.

To sum up, in the electromagnetic shielding device of the invention, since the frame is a frame structure that a strip plate is bent into, the frame does not have joint gaps. Thus, when the cover is combined with the frame, they form a shielding space to enclose the electronic component to prevent the electromagnetic waves generated by the electronic component from leaking and prevent the external electromagnetic waves from permeating into the electromagnetic shielding device.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electromagnetic shielding device, comprising:
a frame formed by bending a strip structure, disposed on a circuit board with an electronic component and enclosing the electronic component; and
a cover having a top portion and a plurality of side portions, wherein the side portions are extended and bent from the top portion;
wherein when the cover is combined with the frame to enclose the electronic component, the side portions and the frame are connected closely to form a shielding space.

2. The electromagnetic shielding device according to claim 1, wherein a joint gap is formed between each two adjacent side portions of the side portions, the top portion has a plurality of first depressed portions, each of the first depressed portions is near to the joint gap between the two adjacent side portions, and when the cover is combined with the frame, the first depressed portions prevent the joint gaps from exposing the shielding space.

3. The electromagnetic shielding device according to claim 1, wherein the top portion has a plurality of second depressed portions, and the second depressed portions are arranged at the top portion near to the side portions.

4. The electromagnetic shielding device according to claim 1, wherein one end of the strip structure is folded to overlap the other end.

5. The electromagnetic shielding device according to claim 1, wherein the frame has at least one second fastening indentation, each of the side portions has at least one first fastening indentation, and when the cover is combined with the frame, the second fastening indentation is fastened with the corresponding first fastening indentation.

6. The electromagnetic shielding device according to claim 1, wherein the frame has a plurality of pins, the circuit board has a plurality of disposed holes, and the pins pass through the disposed holes.

7. The electromagnetic shielding device according to claim 1, wherein a connector is disposed through the frame, and it is electrically connected with the electronic component.

8. The electromagnetic shielding device according to claim 1, wherein the electronic component is a tuner.
